(19) United States
(12) Patent Application Publication
(10) Pub. No.: US 2012/0032233 A1
(43) Pub. Date: Feb. 9, 2012

(54) SILICON-GERMANIUM HETEROJUNCTION BIPOLAR TRANSISTOR AND MANUFACTURING METHOD OF THE SAME

(76) Inventor: Wensheng Qian, Shanghai (CN)

(21) Appl. No.: 13/198,570

(22) Filed: Aug. 4, 2011

(30) Foreign Application Priority Data
Aug. 5, 2010 (CN) 201010245833.6

(51) Int. Cl. H01L 29/70; H01L 21/331

(52) U.S. Cl. 257/197; 438/312; 257/E29.171; 257/E21.387

(57) ABSTRACT

A Silicon-Germanium heterojunction bipolar transistor (SiGe HBT) formed on a silicon substrate, wherein, an active region is isolated by field oxide regions, a collector region is formed in the active region and extends into the bottom of the field oxide regions; pseudo buried layers are formed at the bottom of the field oxide regions. Each of the pseudo buried layers is a lateral distance away from the active region and contacts with a part of the collector region. Deep-hole contacts are formed in the field oxide regions located on top of the pseudo buried layers to pick up the collector region. The present invention can adjust the breakdown voltage of devices through adjusting the lateral distance. A method for manufacturing the SiGe HBT is also disclosed.

### CROSS-REFERENCES TO RELATED APPLICATIONS

This application claims the priority of Chinese patent application number 201010245833.6, filed on Aug. 5, 2010, the entire contents of which are incorporated herein by reference.

### BACKGROUND OF THE INVENTION

1. Field of the Invention

The present invention relates to the manufacturing field of semiconductor integrated circuits and, more particularly, to a Silicon-Germanium heterojunction bipolar transistor(SiGe HBT). The present invention also relates to a manufacturing method of SiGe HBT.

2. Description of Related Art

With the growing maturity of Silicon-Germanium (SiGe) process, radio frequency circuit integration is becoming more and more popular. The radio frequency receiving, radio frequency emission and switching, etc. are all tending toward integration, so the low noise amplifier (LNA) for amplifying received signals and the power amplifier (PA) for amplifying emitted signals shall be fabricated on the same chip. Therefore, it is required to design a high-voltage Silicon-Germanium heterojunction bipolar transistor (SiGe HBT) with different breakdown voltages by only changing the layout on the same technology platform to satisfy the demands of different amplifiers.

Traditional high-voltage SiGe HBTs change the breakdown voltage of the devices by changing the thickness and doping concentration of local collector regions which are grown by lightly-doped epitaxy on heavily-doped N-type buried layer (NBL). The pick-up of collector regions is realized through connecting N+ Sinker to N-type buried layer (NBL). Therefore, traditional high-voltage SiGe HBTs could only achieve different breakdown voltages by change of process. SiGe HBTs that can not realize different breakdown voltages on the same chip restrict the system integration of radio frequency circuits.

### SUMMARY OF THE INVENTION

An objective of the invention is to provide a Silicon-Germanium heterojunction bipolar transistor (SiGe HBT), which can drastically increase the breakdown voltage of devices, adjust the breakdown voltage of devices only by changing the layout without changing the process, facilitate the realization of system integration of devices with different breakdown voltages, and also can reduce the regions of devices, maintain higher cutoff frequency and reduce parasitic resistances of collectors. Another objective of the invention is to provide a method for the SiGe HBT manufacturing.

To achieve the above objective, the invention provides a SiGe HBT, formed on a P-type silicon substrate, where an active region is isolated by field oxide regions. The SiGe HBT comprises:

a collector region, comprising an N-type ion implantation region formed in the active region, deeper than the bottom of the field oxide regions, and extending laterally into the bottom of the field oxide regions located on both sides of the active region;

pseudo buried layers, respectively formed at the bottom of the field oxide regions located on both sides of the active region, each pseudo buried layer comprising an N-type ion implantation region and being a lateral distance away from the active region, and contacting with a part of the collector region which extends laterally into the bottom of the field oxide regions, wherein the breakdown voltage of the Silicon-Germanium heterojunction bipolar transistor is adjusted through adjusting the lateral distance between the pseudo buried layer and the active region, and electrodes of the collector region are picked up through deep-hole contacts formed in the field oxide regions located on the top of the pseudo buried layer;

a base region, comprising a P-type Silicon-Germanium epitaxial layer formed on the silicon substrate, the P-type Silicon-Germanium epitaxial layer comprising an intrinsic base region and an extrinsic base region, wherein the intrinsic base region is formed on the top of the active region and contacts with the collector region, and the extrinsic base region is formed above the field oxide regions and is used for forming electrodes of the base region;

an emitter region, comprising an N-type polysilicon layer formed on the top of the intrinsic base region and contacting with the intrinsic base region.

In one embodiment of the invention, the process conditions of the N-type ion implantation of the collector region are: the implantation dose is 1 e12 cm⁻²˜5 e14 cm⁻², and the implantation energy is 50 KeV˜500 KeV.

In one embodiment of the invention, the process conditions of the N-type ion implantation of the pseudo buried layer are: the implantation dose is 1 e14 cm⁻²˜1 e16 cm^{—2}, and the implantation energy is 1 KeV˜100 KeV.

In one embodiment of the invention, the Silicon-Germanium heterojunction bipolar transistor comprising:

a first window dielectric layer, in which a first window for the base region is formed, wherein the first window defines the position and size of the intrinsic base region, and the first window is located on the top of the active region and the size of the first window is larger than or equal to that of the active region, the first window dielectric layer comprising:

a first silicon oxide film, forming on the silicon substrate;

a polysilicon film, forming on the first silicon oxide film.

In one embodiment of the invention, the P-type Silicon-Germanium epitaxial layer adopts in-situ boron doping or boron ion implantation whose process conditions are: the implantation dose is 1 e14 cm⁻²˜1 e16 cm⁻², and the implantation energy is 1 KeV˜50 KeV; and the germanium is in trapezoidal or triangular distribution.

In one embodiment of the invention, the Silicon-Germanium heterojunction bipolar transistor comprising:

a second window dielectric layer, in which a second window for the emitter region is formed on the top of the intrinsic base region, wherein the size of the second window is smaller than that of the active region, the second window dielectric layer comprising:

a second silicon oxide film, forming on the P-type Silicon-Germanium epitaxial layer;

a silicon nitride film, forming on the second silicon oxide film.

In one embodiment of the invention, the N-type polysilicon of the emitter region is doped through N-type ion implantation whose process conditions are: the implantation dose is 1 e14 cm⁻²˜1 e16 cm⁻², and the implantation energy is 10 KeV˜200 KeV.

In one embodiment of the invention, silicon oxide spacers are formed on both sides of the emitter region.

In one embodiment of the invention, both the emitter region and the extrinsic base region are covered with silicide.

In one embodiment of the invention, the deep-hole contacts are formed through making deep holes in the field oxide regions located on the top of the pseudo buried layers and filling tungsten into the deep holes after depositing titanium/titanium nitride to form metal diffusion barriers.

To achieve the above objective, the invention also provides a manufacturing method of a Silicon-Germanium heterojunction bipolar transistor. The method comprises the following steps:

step 1: forming shallow trench isolations (STI) and an active region in a P-type silicon substrate;

step 2: forming pseudo buried layers by conducting N-type ion implantation at the bottom of the shallow trench isolations (STI) located on both sides of the active region, wherein each of the pseudo buried layers is a lateral distance away from the active region, and the breakdown voltage of the Silicon-Germanium heterojunction bipolar transistor is adjusted through adjusting the lateral distance between the pseudo buried layer and the active region;

step 3: filling silicon oxide into the shallow trench isolations (STI) to form field oxide regions;

step 4: forming a collector region by conducting N-type ion implantation in the active region, wherein the collector region is deeper than the bottom of the field oxide regions, and the collector region extends laterally into the bottom of the field oxide regions located on both sides of the active region and contacts with the pseudo buried layers;

step 5: forming a base region through P-type Silicon-Germanium epitaxial growth on the silicon substrate, wherein, the base region comprises an intrinsic base region and an extrinsic region; the intrinsic region is formed on the top of the active region and contacts with the collector region, and the extrinsic base region is formed above the field oxide regions and is used for forming electrodes of the base region;

step 6: forming an emitter region through growing N-type polysilicon on the top of the intrinsic base region, wherein the emitter region contacts with the intrinsic base region;

step 7: forming deep-hole contacts in the field oxide regions on the top of the pseudo buried layers to pick up the collector region.

In one embodiment of the invention, the process conditions of N-type ion implantation of the pseudo buried layer in Step 2 are: the implantation dose is 1 e14 cm⁻²˜1 e16 cm⁻², and the implantation energy is 1 KeV˜100 KeV.

In one embodiment of the invention, the process conditions of N-type ion implantation of the collector region in Step 4 are: the implantation dose is 1 e12 cm⁻²˜5 e14 cm⁻², and the implantation energy is 50 KeV˜500 KeV.

In one embodiment of the invention, the manufacturing method of a Silicon-Germanium heterojunction bipolar transistor comprising the following steps in Step 5:

steps for forming a first window dielectric layer for the base region, comprising: forming a first silicon oxide film on the silicon substrate and forming a polysilicon film on the first silicon oxide film;

steps for forming a first window for the base region, comprising: forming the first window by etching the first window dielectric layer on the top of the active region, wherein, the size of the first window is larger than or equal to that of the active region.

In one embodiment of the invention, the P-type Silicon-Germanium epitaxial layer in Step 5 adopts in-situ boron doping or boron ion implantation whose process conditions are: the implantation dose is 1 e14 cm⁻²˜1 e16 cm⁻², and the implantation energy is 1 KeV˜50 KeV; and the germanium is in trapezoidal or triangular distribution.

In one embodiment of the invention, the manufacturing method of a Silicon-Germanium heterojunction bipolar transistor according to claim 11, comprising the following steps in Step 6:

steps for forming a second window dielectric layer for the emitter region, comprising: forming a second silicon oxide film on the P-type Silicon-Germanium epitaxial layer, and forming a silicon nitride film on the second silicon oxide film;

steps for forming a second window for the emitter region, comprising: forming the second window through etching the second window dielectric layer on the top of the intrinsic base region, wherein, the size of the window of the emitter region is smaller than that of the active region.

In one embodiment of the invention, the N-type polysilicon of the emitter region in Step 6 is doped through N-type ion implantation, and the process conditions of the N-type ion implantation are: the implantation dose is 1 e14 cm⁻²˜1 e16 cm⁻², and the implantation energy is 10 KeV˜200 KeV.

In one embodiment of the invention, in Step 7, the deep-hole contacts are formed through making deep holes in the field oxide regions located on the top of the pseudo buried layers and filling tungsten into the deep holes after depositing titanium/titanium nitride to form metal diffusion barriers.

In one embodiment of the invention, the manufacturing method of a Silicon-Germanium heterojunction bipolar transistor according to claim 11, further comprising the steps for forming silicide on the surface of the emitter region and the extrinsic base region.

The present invention has the following effective effects:

1. The present invention drastically increases the breakdown voltage of the SiGe HBT because the pseudo buried layer is used to replace the N-type buried layer (NBL) in the SiGe HBT in the prior art, which greatly increases the breakdown voltage of the BC junction, that is the breakdown voltage of PN junction formed between the base region and the collector region, and also makes the breakdown of BC junction determined by the lateral depletion region instead of the vertical depletion region. The lateral BC junction depletion region may stop in the pseudo buried layers, so the size of the collector region that extends laterally into the bottom of the field oxide regions will determine the breakdown voltage of the BC junction and then determine the breakdown voltage (BVCEO) of the SiGe HBT. Therefore, the present invention increases the breakdown voltage of the BC junction of devices and the breakdown voltage (BVCEO) of the SiGe HBT through increasing the size of a collector region which extends laterally into field oxide regions.

2. The present invention is favorable for the SiGe HBT devices with different voltages to integrate on the same chip. Because, with the structure of the SiGe HBT devices in the present invention, the breakdown voltage of the SiGe HBT devices can be adjusted conveniently only by changing the size of the collector region that extends laterally into the bottom of the field oxide regions. Therefore, without changing the process conditions of devices, the present invention can produce serial high-voltage SiGe HBT devices with different breakdown voltages on the same chip only by changing of the layout. Therefore, the integration of the SiGe HBT devices with different breakdown voltages can be realized. At the same time, the integration of devices in the present invention does not need the change of the process conditions of the devices, that is, the depth and dosage concentration of the collector region are not changed, so the equivalent resistance and the BC junction capacitance in the collector region will not show a large degree of change, thus the cutoff frequency will remain relatively stable.

3. The present invention can also reduce the size of devices. The SiGe HBT in the present invention adopts a deep-hole contact to pick up the pseudo buried layer as the collector, so the problem of a too large area of the devices caused by adopting N-sinker for the existing SiGe HBT is avoided, and at the same time, the parasitic resistance of the collector is also reduced.

### BRIEF DESCRIPTION OF THE DRAWINGS

These and other features, aspects, and advantages of the present invention will become better understood with regard to the following description, appended claims, and accompanying drawings.

FIG. 1 is a structure diagram of the Silicon-Germanium heterojunction bipolar transistor in an embodiment of the present invention;

FIGS. 2-12 are structure diagrams of the Silicon-Germanium heterojunction bipolar transistor in various steps of the manufacturing method in an embodiment of the present invention.

### DETAILED DESCRIPTION OF THE INVENTION

As is shown in FIG. 1, it is a structure diagram of the Silicon-Germanium heterojunction bipolar transistor(SiGe HBT) in the embodiment of the present invention. The SiGe HBT in the embodiment of the present invention is formed on a P-type silicon substrate 101, and an active region is isolated by field oxide regions 102. The SiGe HBT includes:

A collector region 104, consisting of an N-type ion implantation region formed in the active region, wherein the collector region 104 is deeper than the bottom of the field oxide regions 102, and the collector region 104 extends laterally into the bottom of the field oxide regions 102 on both sides of the active region. The process conditions of the N-type ion implantation of the collector region 104 are: the implantation dose is 1 e12 cm⁻²˜5 e14 cm⁻² and the implantation energy is 50 KeV˜500 KeV.

Pseudo buried layers 103, each consisting of an N-type ion implantation region and respectively formed at the bottom of the field oxide regions 102 located on both sides of the active region, wherein each pseudo buried layer 103 is a lateral distance d away from the active region, and contacts with a part of the collector region 104 which extends laterally into the bottom of the field oxide regions 102. The breakdown voltage of the SiGe HBT can be adjusted through adjusting the lateral distance d between the pseudo buried layer 103 and the active region. The electrodes of the collector region 104 are picked up through deep-hole contacts 112 formed in the field oxide regions 102 on the top of the pseudo buried layers 103. The process conditions of the N-type ion plantation of the pseudo buried layers 103 are: the implantation dose is 1 e14 cm⁻²˜1 e16 cm−2, and the implantation energy is 1 KeV˜100 KeV. The deep-hole contacts 112 are formed through making deep holes in the field oxide regions 102 located on the top of the pseudo buried layers 103 and filling tungsten into the deep holes after depositing titanium/titanium nitride to form metal diffusion barriers.

A base region 107, consisting of a P-type Silicon-Germanium epitaxial layer formed on the silicon substrate 101, includes an intrinsic base region and an extrinsic base region, wherein the intrinsic base region is formed on the top of the active region and contacts with the collector region 104, and the extrinsic base region is formed on the top of the field oxide regions 102 and is used to form the electrode of the base region 107. The position and size of the intrinsic base region is defined by a window of the base region. The window of the base region is located on the top of the active region and the size of the window of the base region is larger than or equal to that of the active region. The position and size of the window of the base region is defined by a window dielectric layer of the base region, and the window dielectric layer includes a first silicon oxide film 105 and a polysilicon film 106. The first silicon oxide film 105 is formed on the silicon substrate 101 and the polysilicon film 106 is formed on the first silicon oxide film 105. The P-type Silicon-Germanium epitaxial layer adopts boron dopant whose process is in-situ doping, or ion implantation. The implantation conditions are: the implantation dose is 1 e14 cm⁻²˜1 e16 cm⁻², and the implantation energy is 1 KeV˜50 KeV. The germanium is in tapezoidal or triangular distribution.

An emitter region 110 consists of N-type polysilicon formed on the top of the intrinsic base region and contacts with the intrinsic base region. The position and size of the emitter region 110 is defined by a window of the emitter region, and the window of the emitter region is located on the top of the intrinsic base region and the size of the window of the emitter region is smaller than that of the active region. The position and size of the window of the emitter region is defined by a window dielectric layer of the emitter region. The window dielectric layer includes a second silicon oxide film 108 and a silicon nitride film 109. The second silicon oxide film 108 is formed on the P-type Silicon-Germanium epitaxial layer, and the silicon nitride film 109 is formed on the second silicon oxide film 108. The N-type polysilicon of the emitter region is doped through N-type ion implantation. The process conditions of the N-type ion implantation are: the implantation dose is 1 e14 cm⁻²˜1 e16 cm⁻² and the implantation energy is 10 KeV˜200 KeV. The silicon oxide spacers 111 are formed on both sides of the emitter region 110. Both the emitter region 110 and the extrinsic base region are covered with silicide.

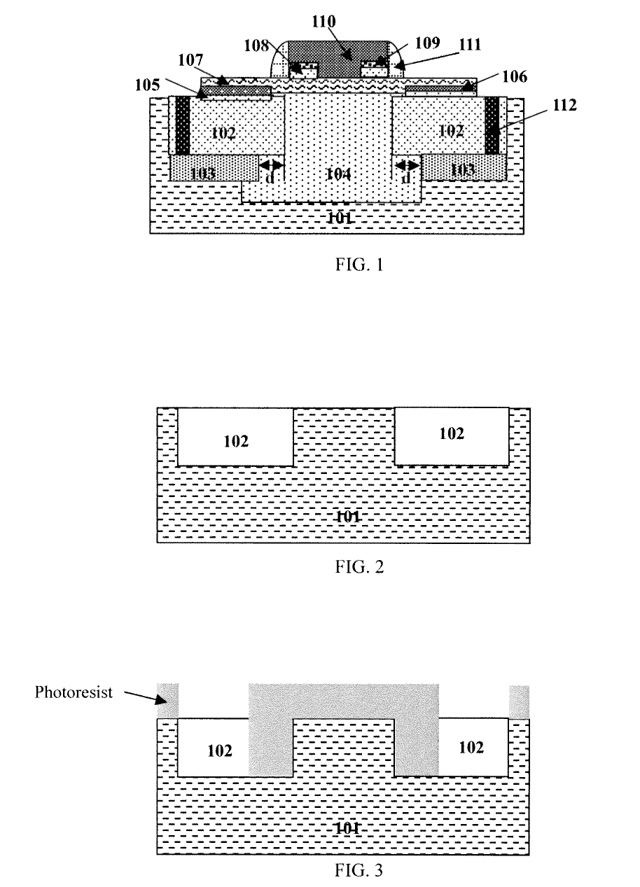

As shown in FIGS. 2-12, they are the structure diagrams of the SiGe HBT in all the steps of the embodiment in the present invention. The manufacturing method of the embodiment in the present invention includes the following steps:

Step 1: as shown in FIG. 2, the shallow trench isolations 102 and the active region are formed in the P-type silicon substrate.

Step 2: form the pseudo buried layers 103. First of all, as shown in FIG. 3, define the area of the pseudo buried layer 103 by photoetching, that is, deposit a photoresist layer on the silicon substrate 101 and open implantation windows to expose the corresponding areas for the pseudo buried layer 103 ion implantation. Each implantation window is a lateral distance d away from the active area and through adjusting the lateral distance d, the breakdown voltage of the SiGe HBT is adjusted. As shown in FIG. 4, form the pseudo buried layers 103 at the bottom of the shallow trench isolations 102 on both sides of the active region by N-type ion implantation in the implantation windows. The pseudo buried layers 103 respectively have a lateral distance away from the active region, and this distance is defined by the implantation window of the pseudo buried layer 103. The process conditions of N-type ion implantation of the pseudo buried layers 103 are: the implantation dose is 1 e14 cm⁻²−1 e16 cm⁻², and the implantation energy is 1 KeV˜100 KeV.

Step 3: as shown in FIG. 4, form the field oxide regions 102, i.e., the shallow trench isolation regions, through filling silicon oxide into the shallow trench isolation.

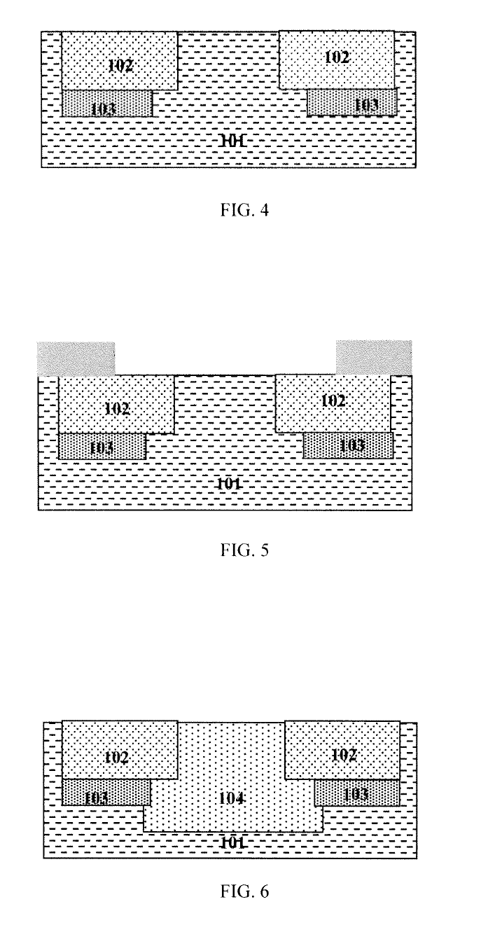

Step 4: form the collector region 104. First of all, as shown in FIG. 5, define the area of the collector region 104 through photoetching, that is, form the protective window of the collector region 104 for the ion implantation of the collector region 104. As shown in FIG. 6, with the protection of the protective window of the collector region implant N-type ion in the active region to form the collector region 104. The collector region 104 is deeper than the bottom of the field oxide regions 102, and the collector region 104 extends laterally into the bottom of the field oxide regions 102 located on both sides of the active region, partly overlaps with the pseudo buried layers 103 and forms good contacts. At last, conduct the heat drive-in process. The process conditions of N-type ion implantation of the collector region 104 are: the implantation dose is 1 e12 cm⁻²˜5 e14 cm⁻² and the implantation energy is 50 KeV˜500 KeV.

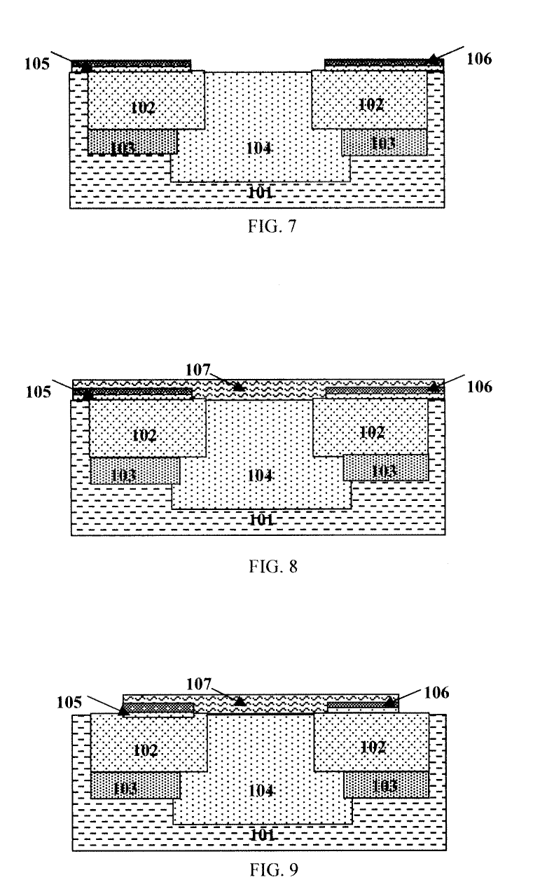

Step 5: form the base region 107. First of all, as shown in FIG. 7, form the window dielectric layer of the base region: form a first silicon oxide film 105 on the silicon substrate 101, and form a polysilicon film 106 on the first silicon oxide film 105. Second, form the window of the base region through etching the window dielectric layer of the base region above the active region, i.e., etching the first silicon oxide film 105 and the polysilicon film 106. The size of the window of the base region is larger than or equal to that of the active region to make sure that the Silicon-Germanium epitaxial layers of the base region to be grown on the active region are single crystalline layers.

As shown in FIG. 8, grow P-type Silicon-Germanium epitaxial layer on the silicon substrate 101. As shown in FIG. 9, etch the P-type Silicon-Germanium epitaxial layer and the window dielectric layer of the base region outside the base region 107 to form the base region 107, where the part formed on the top of the active region is the intrinsic base region contacting with the collector region 104; the part formed above the field oxide regions 102 is the extrinsic base region. Most of the extrinsic base region is isolated by the window dielectric layer of the base region from the field oxide regions 102, and the window dielectric layer of the base region can reduce the junction capacitance between the extrinsic base region and the collector region. The P-type Silicon-Germanium epitaxial layer adopts in-situ boron doping or boron ion implantation whose process conditions are: the implantation dose is 1 e14 cm−2˜1 e16 cm−2 and the implantation energy is 1 KeV˜50 KeV. The germanium is in trapezoidal or triangular distribution.

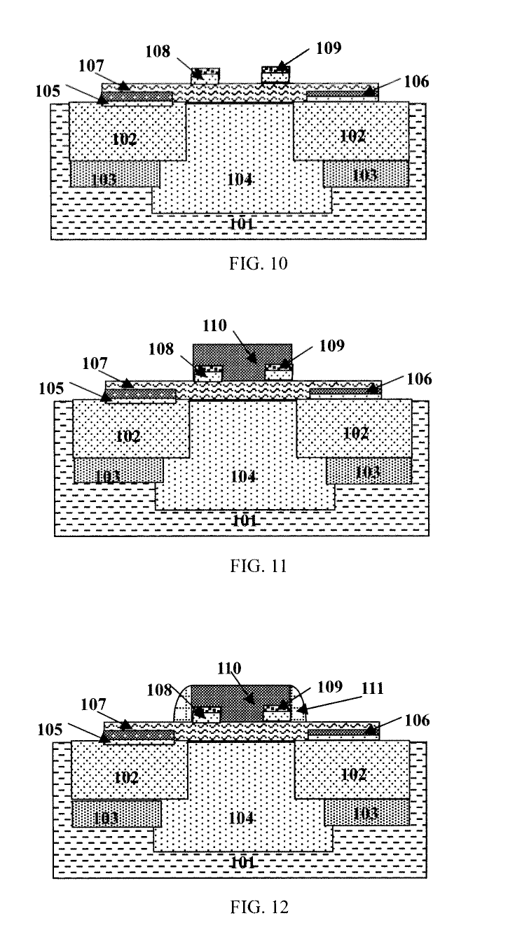

Step 6: form the emitter region 110. First of all, as shown in FIG. 10, form the window dielectric layer of the emitter region: form a second silicon oxide film 108 on the P-type Silicon-Germanium epitaxial layer of the base region 107, and form a silicon nitride film 109 on the second silicon oxide film 108; form the window of the emitter region through etching the window dielectric layer of the emitter region above the intrinsic base region, i.e., etching the second silicon oxide film 108 and the silicon nitride film 109. The size of the window of the emitter region is smaller than that of the active region to avoid influence to the intrinsic BE junction caused by the part of the P-type Silicon-Germanium epitaxial layer at the margin of the active region with relatively poor quality of epitaxy. As shown in FIG. 11, grow N-type polysilicon on the intrinsic base region and form the emitter region 110 through etching the N-type polysilicon, and the emitter region 110 contacts with the intrinsic base region. The N-type polysilicon of the emitter region is doped through N-type ion implantation. The process conditions of the N-type ion implantation are: the implantation dose is 1 e14 cm⁻²˜1 e16 cm⁻² and the implantation energy is 10 KeV˜200 KeV.

Step 7: as shown in FIG. 12, implant P-type impurities in the extrinsic base region of the base region 107, and form the electrode of the base region on the extrinsic base region. Form the silicon oxide spacers 111 on both sides of the emitter region 110. The silicon oxide spacers 111 can avoid silicide bridging between the emitter region 110 and the extrinsic base region. Deposit silicide on the emitter region 110 and the extrinsic base region, which can reduce the parasitic resistance. As shown in FIG. 1, form deep-hole contacts 112 in the field oxide regions 102 on the top of the pseudo buried layers 103 to pick up the collector regions 104. The fabrication process of the deep-hole contact 112 includes making a deep hole in the field oxide region 102 located on the top of the pseudo buried layer 103, filling tungsten into the deep hole after depositing titanium/titanium nitride to form a metal diffusion barrier.

The manufacturing method of the embodiment in the present invention also includes the processes for forming the contacting holes of the extrinsic base region and the emitter region 110, and other subsequent processes.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A Silicon-Germanium heterojunction bipolar transistor, formed on a P-type silicon substrate, where an active region is isolated by field oxide regions, comprising:
a collector region, comprising an N-type ion implantation region formed in the active region, deeper than the bottom of the field oxide regions, and extending laterally into the bottom of the field oxide regions located on both sides of the active region;
pseudo buried layers, respectively formed at the bottom of the field oxide regions located on both sides of the active region, each pseudo buried layer comprising an N-type ion implantation region and being a lateral distance away from the active region, and contacting with a part of the collector region which extends laterally into the bottom of the field oxide regions, wherein the breakdown voltage of the Silicon-Germanium heterojunction bipolar transistor is adjusted through adjusting the lateral distance between the pseudo buried layer and the active region, and electrodes of the collector region are picked up through deep-hole contacts formed in the field oxide regions located on the top of the pseudo buried layer;
a base region, comprising a P-type Silicon-Germanium epitaxial layer formed on the silicon substrate, the P-type Silicon-Germanium epitaxial layer comprising an intrinsic base region and an extrinsic base region, wherein the intrinsic base region is formed on the top of the active region and contacts with the collector region, and the extrinsic base region is formed above the field oxide regions and is used for forming electrodes of the base region;
an emitter region, comprising an N-type polysilicon layer formed on the top of the intrinsic base region and contacting with the intrinsic base region.

2. The Silicon-Germanium heterojunction bipolar transistor according to claim 1, wherein, the process conditions of the N-type ion implantation of the collector region are: the implantation dose is 1 e12 cm⁻²˜5 e14 cm⁻², and the implantation energy is 50 KeV˜500 KeV.

3. The Silicon-Germanium heterojunction bipolar transistor according to claim 1, wherein, the process conditions of the N-type ion implantation of the pseudo buried layer are: the implantation dose is 1 e14 cm⁻²˜1 e16 cm⁻², and the implantation energy is 1 KeV˜100 KeV.

4. The Silicon-Germanium heterojunction bipolar transistor according to claim 1, further comprising:
a first window dielectric layer, in which a first window for the base region is formed, wherein the first window defines the position and size of the intrinsic base region, and the first window is located on the top of the active region and the size of the first window is larger than or equal to that of the active region, the first window dielectric layer comprising:
a first silicon oxide film, forming on the silicon substrate;
a polysilicon film, forming on the first silicon oxide film.

5. The Silicon-Germanium heterojunction bipolar transistor according to claim 1, wherein, the P-type Silicon-Germanium epitaxial layer adopts in-situ boron doping or boron ion implantation whose process conditions are: the implantation dose is 1 e14 cm⁻²˜1 e16 cm⁻², and the implantation energy is 1 KeV˜50 KeV; and the germanium is in trapezoidal or triangular distribution.

6. The Silicon-Germanium heterojunction bipolar transistor according to claim 1, further comprising:
a second window dielectric layer, in which a second window for the emitter region is formed on the top of the intrinsic base region, wherein the size of the second window is smaller than that of the active region, the second window dielectric layer comprising:
a second silicon oxide film, forming on the P-type Silicon-Germanium epitaxial layer;
a silicon nitride film, forming on the second silicon oxide film.

7. The Silicon-Germanium heterojunction bipolar transistor according to claim 1, wherein, the N-type polysilicon of the emitter region is doped through N-type ion implantation whose process conditions are: the implantation dose is 1 e14 cm⁻²˜1 e16 cm⁻², and the implantation energy is 10 KeV˜200 KeV.

8. The Silicon-Germanium heterojunction bipolar transistor according to claim 1, wherein, silicon oxide spacers are formed on both sides of the emitter region.

9. The Silicon-Germanium heterojunction bipolar transistor according to claim 1, wherein, both the emitter region and the extrinsic base region are covered with silicide.

10. The Silicon-Germanium heterojunction bipolar transistor according to claim 1, wherein, the deep-hole contacts are formed through making deep holes in the field oxide regions located on the top of the pseudo buried layers and filling tungsten into the deep holes after depositing titanium/titanium nitride to form metal diffusion barriers.

11. A manufacturing method of a Silicon-Germanium heterojunction bipolar transistor, comprising the following steps:
step 1: forming shallow trench isolations (STI) and an active region in a P-type silicon substrate;
step 2: forming pseudo buried layers by conducting N-type ion implantation at the bottom of the shallow trench isolations (STI) located on both sides of the active region, wherein each of the pseudo buried layers is a lateral distance away from the active region, and the breakdown voltage of the Silicon-Germanium heterojunction bipolar transistor is adjusted through adjusting the lateral distance between the pseudo buried layer and the active region;
step 3: filling silicon oxide into the shallow trench isolations (STI) to form field oxide regions;
step 4: forming a collector region by conducting N-type ion implantation in the active region, wherein the collector region is deeper than the bottom of the field oxide regions, and the collector region extends laterally into the bottom of the field oxide regions located on both sides of the active region and contacts with the pseudo buried layers;
step 5: forming a base region through P-type Silicon-Germanium epitaxial growth on the silicon substrate, wherein, the base region comprises an intrinsic base region and an extrinsic region; the intrinsic region is formed on the top of the active region and contacts with the collector region, and the extrinsic base region is formed above the field oxide regions and is used for forming electrodes of the base region;
step 6: forming an emitter region through growing N-type polysilicon on the top of the intrinsic base region, wherein the emitter region contacts with the intrinsic base region;
step 7: forming deep-hole contacts in the field oxide regions on the top of the pseudo buried layers to pick up the collector region.

12. The manufacturing method of a Silicon-Germanium heterojunction bipolar transistor according to claim 11, wherein, the process conditions of N-type ion implantation of the pseudo buried layer in Step 2 are: the implantation dose is 1 e14 cm⁻²˜1 e16 cm⁻², and the implantation energy is 1 KeV˜100 KeV.

13. The manufacturing method of a Silicon-Germanium heterojunction bipolar transistor according to claim 11, wherein, the process conditions of N-type ion implantation of the collector region in Step 4 are: the implantation dose is 1 e12 cm⁻²˜5 e14 cm⁻², and the implantation energy is 50 KeV˜500 KeV.

14. The manufacturing method of a Silicon-Germanium heterojunction bipolar transistor according to claim 11, comprising the following steps in Step 5:
steps for forming a first window dielectric layer for the base region, comprising: forming a first silicon oxide film on the silicon substrate and forming a polysilicon film on the first silicon oxide film;
steps for forming a first window for the base region, comprising: forming the first window by etching the first window dielectric layer on the top of the active region, wherein, the size of the first window is larger than or equal to that of the active region.

15. The manufacturing method of a Silicon-Germanium heterojunction bipolar transistor according to claim 11, wherein, the P-type Silicon-Germanium epitaxial layer in Step 5 adopts in-situ boron doping or boron ion implantation whose process conditions are: the implantation dose is 1 e14 cm⁻²˜1 e16 cm⁻², and the implantation energy is 1 KeV˜50 KeV; and the germanium is in trapezoidal or triangular distribution.

16. The manufacturing method of a Silicon-Germanium heterojunction bipolar transistor according to claim 11, comprising the following steps in Step 6:
steps for forming a second window dielectric layer for the emitter region, comprising: forming a second silicon oxide film on the P-type Silicon-Germanium epitaxial layer, and forming a silicon nitride film on the second silicon oxide film;
steps for forming a second window for the emitter region, comprising: forming the second window through etching the second window dielectric layer on the top of the intrinsic base region, wherein, the size of the window of the emitter region is smaller than that of the active region.

17. The manufacturing method of a Silicon-Germanium heterojunction bipolar transistor according to claim 11, wherein, the N-type polysilicon of the emitter region in Step 6 is doped through N-type ion implantation, and the process conditions of the N-type ion implantation are: the implantation dose is 1 e14 cm⁻²˜1 e16 cm⁻², and the implantation energy is 10 KeV˜200 KeV.

18. The manufacturing method of a Silicon-Germanium heterojunction bipolar transistor according to claim 11, wherein, in Step 7, the deep-hole contacts are formed through making deep holes in the field oxide regions located on the top of the pseudo buried layers and filling tungsten into the deep holes after depositing titanium/titanium nitride to form metal diffusion barriers.

19. The manufacturing method of a Silicon-Germanium heterojunction bipolar transistor according to claim 11, further comprising the steps for forming silicide on the surface of the emitter region and the extrinsic base region.
